(19) United States
(12) Patent Application Publication
(10) Pub. No.: US 2009/0140332 A1
(43) Pub. Date: Jun. 4, 2009

(54) SEMICONDUCTOR DEVICE AND METHOD OF FABRICATING THE SAME

(76) Inventor: Dae-Kyeun Kim, Yongin-si (KR)

Correspondence Address: SHERR & VAUGHN, PLLC, 620 HERNDON PARKWAY, SUITE 200, HERNDON, VA, 20170, US

(21) Appl. No.: 12/325,165

(22) Filed: Nov. 29, 2008

(30) Foreign Application Priority Data
Nov. 30, 2007 (KR) 10-2007-0123565

(51) Int. Cl. H01L 29/78; H01L 21/336

(52) U.S. Cl. 257/330; 438/270; 257/E29.262; 257/E21.41

(57) ABSTRACT

A semiconductor device and a method of fabricating the same includes a groove formed in a semiconductor substrate, a gate electrode formed in the groove, source/drain regions disposed adjacent sidewalls of the gate electrode, and spacers interposed between the gate electrode and the source/drain regions such that the uppermost surface of the source/drain regions, the uppermost surface of the gate electrode and the uppermost surface of the spacers are formed on the same plane.

The present application claims priority under 35 U.S.C. §119 to Korean Patent Application No. 10-2007-0123565 (filed on Nov. 30, 2007), which is hereby incorporated by reference in its entirety.

### BACKGROUND

With the development of information processing techniques, there has been a demand for high integration and high density semiconductor devices. Accordingly, problems arise in semiconductor devices such as spaces between semiconductor devices are not completely filled with a material such as a dielectric film or the like, thereby generating a void.

### SUMMARY

Embodiments relate to a semiconductor device and a method of fabricating the same that prevents or otherwise reduces void generation.

Embodiments relate to a semiconductor device and a method of fabricating the same that can be easily connected to a contact electrode or the like.

Embodiments relate to a semiconductor device that may include at least one of the following: a gate electrode disposed on and/or over an inner side of a groove formed in a semiconductor substrate; a gate dielectric film disposed between a bottom of the gate electrode and the semiconductor substrate; source/drain regions disposed at the side surface of the gate electrode; and spacers interposed between the gate electrode and the source/drain regions.

Embodiments relate to a method of fabricating a semiconductor device that may include at least one of the following: forming a groove in a semiconductor device; and then forming spacers on and/or over an inner side surface of the groove; and then forming a gate dielectric film on and/or over a bottom surface of the groove; and then forming a gate electrode at inner sides of the spacer and on and/or over the gate dielectric film; and then forming LDD regions at outer sides of the spacer and under the spacers; and then forming source/drain regions at outer sides of the spacers and on and/or over the LDD regions.

Embodiments relate to a method of fabricating a semiconductor device that may include at least one of the following: forming a first groove in a semiconductor device; and then forming a gate dielectric film on and/or over an inner side of the first groove; and then forming a gate electrode on and/or over an inner side of the gate dielectric film; and then forming a second groove by etching the semiconductor substrate on and/or over an outer side of the gate dielectric film; and then forming LDD regions below the second groove; and then forming source/drain regions on and/or over one side of the gate electrode.

Embodiments relate to a method that may include at least one of the following: forming a groove in a semiconductor device; and then forming spacers in the groove; and then forming a gate dielectric film over a bottom surface of the groove; and then forming a gate electrode in the groove between the spacers and over the gate dielectric film; and then forming LDD regions in the semiconductor device contacting sidewalls and a bottom surface of the spacer; and then forming source/drain regions in the semiconductor device contacting sidewalls of the spacers and over the LDD regions.

Embodiments relate to a device that may include at least one of the following: a groove formed in a semiconductor substrate; a gate dielectric film formed over and contacting a bottom surface of the groove; a gate electrode formed in the groove over the gate dielectric film; source/drain regions disposed adjacent the sides of the gate electrode; and spacers interposed between the gate electrode and the source/drain regions such that the uppermost surface of the source/drain regions, the uppermost surface of the gate electrode and the uppermost surface of the spacers are formed on the same plane.

Embodiments relate to a device that may include at least one of the following: a first groove formed in a semiconductor substrate; a gate dielectric film formed over and contacting a the sidewalls and the bottom surface of the first groove; a gate electrode formed in the first groove over the gate dielectric film, the gate electrode including an upper gate electrode portion projecting from the first groove and a lower gate electrode portion formed in the first groove; second grooves formed in the semiconductor substrate; spacers formed in a respective one of the second grooves and contacting sidewalls of the gate dielectric film; source/drain regions formed in the semiconductor substrate and contacting a sidewall of the spacers.

### DRAWINGS

Example FIGS. 1 to 4 illustrate a semiconductor device and a method of fabricating a semiconductor device in accordance with embodiments.

### DESCRIPTION

Example FIG. 1 is a cross-sectional view showing a semiconductor device in accordance with embodiments. Referring to example FIG. 1, the semiconductor device includes a semiconductor substrate 100, a gate electrode 200, a gate dielectric film 300, spacers 400, source/drain regions 600 and LDD regions 500.

The semiconductor substrate 100 includes a region 110 to which an n-type impurity is implanted, a device isolation film 130 and a p-well 120 to which a p-type impurity is implanted. The device isolation film 130 is formed by performing a Shallow Trench Isolation (STI) process or a LOCOS process in a silicon substrate into which an n-type impurity is implanted. The semiconductor substrate 100 includes a groove 140 formed therein. The groove 140 is formed in the p well 120.

The gate electrode 200 is disposed in the groove 140. More specifically, the gate electrode 200 is disposed between spacers 400 and on and/or over the gate dielectric film 300. The gate electrode 200 includes a polysilicon layer 210 and a first silicide film 200 formed on and/or over the poly silicon layer 210. In accordance with embodiments, the gate electrode 200 may be made of metal instead of polysilicon. The gate dielectric film 300 is disposed on and/or over the bottom surface of the groove 140 and is thereby interposed between the gate electrode 200 and the p-well 120 of the semiconductor substrate 100. The gate dielectric film 300 insulates the bottom portion of the gate electrode 200. As the gate dielectric film 300, material such as silicon oxide (SiOₓ) or the like may be used.

The spacer 400 is disposed at the sidewalls of the groove 140 such that gate dielectric film 300 is formed therebetween. The spacer 400 is disposed on the sidewalls of the gate electrode 200 and the gate dielectric film 300. The spacer 400 is interposed between the gate electrode 200 and source/drain regions 600 to insulate the sidewalls of the gate electrode 200. As the spacer 400, material such as nitride may be used. The source/drain region 600 is formed in the p-well 120 adjacent sides of the gate electrode 200. The source/drain region 600 is formed at a portion of the sidewall of the spacer 400. The source/drain region 600 includes a first region 610 including a high-concentration n-type impurity and a second region 620 including a silicide film 620.

The LDD region 500 is formed below the source/drain region 600 and on and/or over sidewalls and a bottom surface of the spacer 400. The LDD region 500 is formed by implanting impurities such as low-concentration n-type impurities in the p-well 120. The pair of LDD regions 500 are spaced from each other. The gate electrode 200 is formed in the groove 140 of the p-well 120 of the semiconductor substrate 100 such that unevenness is not formed on the uppermost surface of the semiconductor device. Therefore, the semiconductor device in accordance with embodiments can prevent void generation between semiconductor devices. Also, the uppermost surfaces of the gate electrode 200, the spacer 400 and the source/drain region 600 are formed on the same plane (i.e, are coplanar), and thus, the uppermost surface of the semiconductor device is flat. Therefore, it is easy to form a contact electrode on and/or over the gate electrode 200 and the source/drain region 600.

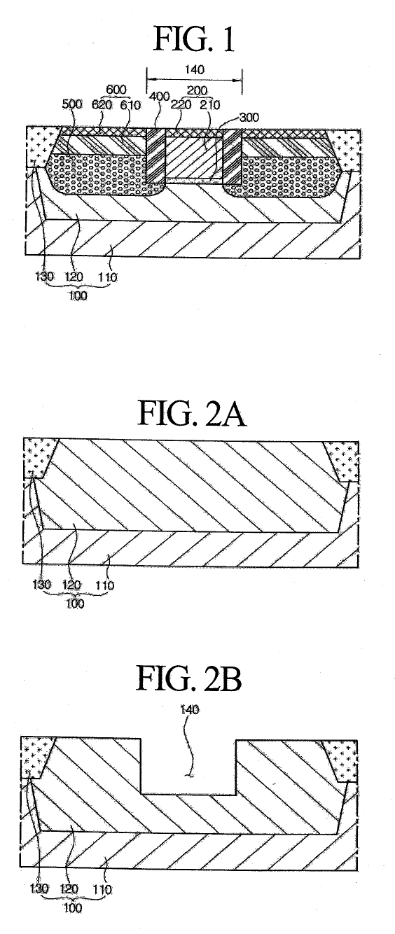

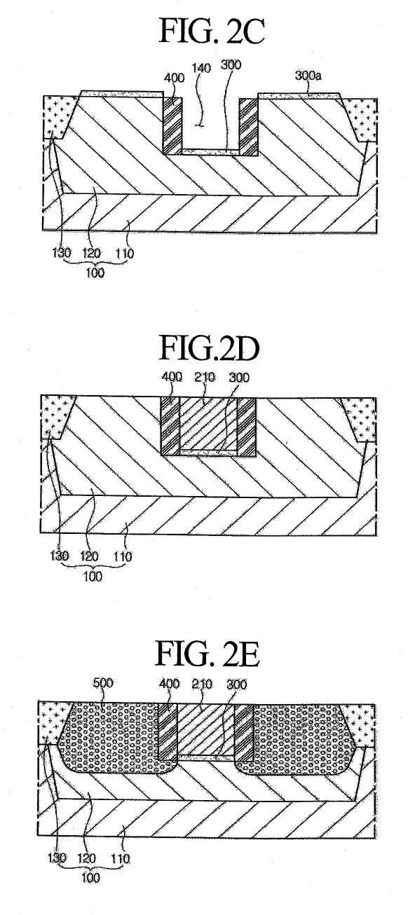

Example FIGS. 2A to 2F are cross-sectional views showing a method of fabricating a semiconductor device in accordance with embodiments. Referring to example FIG. 2A, a trench is formed in a silicon substrate into which an n-type impurity is implanted. The trench is filled with an oxide material, thereby forming a device isolation film 130. Thereafter, a low-concentration p-type impurity is implanted into a region defined by the device isolation film 130 to form a p-well 120, thereby forming a semiconductor substrate 100 including the region 110 to which the n-type impurity is implanted, the device isolation film 130 and the p-well 120.

Referring to example FIG. 2B, a groove 140 is formed in the semiconductor substrate 100. More specifically, a groove 140 is formed in the p-well 120. In order to form the groove 140, a photoresist film is formed on and/or over the semiconductor substrate 100 and then patterned using an exposure process and a development process to thereby form a photoresist pattern which exposes a portion of the p-well 120 where the groove 140 is to be formed. A portion of the p-well 120 is then etched using the photoresist pattern as an etching mask to form the groove 140.

Referring to example FIG. 2C, a nitride film is formed on and/or over the sidewalls and bottom surface of the groove 140 and the entire semiconductor substrate 100. The portion of the nitride film formed on and/or over the semiconductor substrate 100 and a portion of the bottom surface of the groove 140 is removed by performing an isotropic etching, thereby forming a nitride spacer 400. Thereafter, through a thermal oxidation process, an oxide film 300a is formed on and/or over an uppermost surface of the semiconductor substrate 100 and a gate dielectric film 300 is formed on and/or over the bottom surface of the groove 140.

Referring to example FIG. 2D, polysilicon is then formed on and/or over the semiconductor substrate 100 and filling the groove 140. Thereafter, a Chemical Mechanical Polishing (CMP) process is performed to remove the polysilicon and the oxide film 300a from the uppermost surface of the semiconductor substrate 100. Therefore, a gate electrode 210 composed of polysilicon remains in the groove 140. At this time, during the CMP process, a grinding process stops based on the spacer 400, and the oxide film 300a on the semiconductor substrate 100 is removed by the CMP process. Alternatively, the gate electrode 210 can be composed of a metal such as aluminum, copper, tungsten or the like using the same CMP process.

Referring to example FIG. 2E, in order to form the LDD region 500, a low-concentration n-type impurity is implanted into the p-well 120 of the semiconductor substrate 100, and then the p-well 120 of the semiconductor substrate 100 is then subject to an annealing process such as a rapid temperature annealing (RTA). During the annealing process, the implanted n-type impurity is diffused up to the bottom of the spacer 400. Thereby, the LDD region 500 is formed on a portion of the sidewall and also the bottom surface of the spacer 400.

Referring to example FIG. 2F, a high-concentration n-type impurity is the implanted into the active region, thereby forming a region 610 including a high-concentration n-type impurity adjacent the sides of the gate electrode 210, particularly, on the sidewall of the spacer 400. Thereafter, a metal layer is formed on and/or over the semiconductor substrate 100 including the gate electrode 210 and the region 610. As the metal layer, material such as nickel, cobalt, tantalum, platinum, titanium or the like may be used. Thereafter, an annealing process and a cleansing process are performed on the metal layer to form a first silicide film 220 formed on and/or over the gate electrode 210 and second silicide film 620 formed on and/or over the reigon 610 of the source/drain region 600.

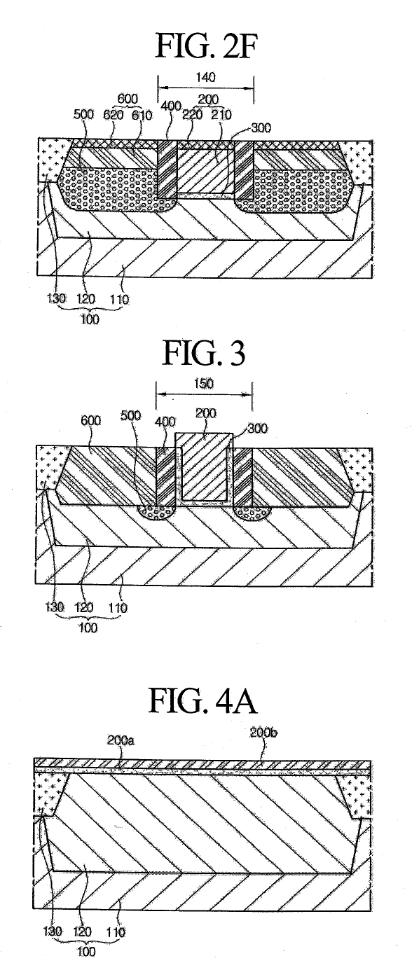

Example FIG. 3 is a cross-sectional view of a semiconductor device in accordance with embodiments. Referring to example FIG. 3, the semiconductor device includes a semiconductor substrate 100, a gate electrode 200, a gate dielectric film 300, spacers 400, LDD regions 500 and source/drain regions 600.

The semiconductor substrate 100 includes a region 110 into which an n-type impurity is implanted, a device isolation film 130 and a p-well 120 into which a p-type impurity is implanted. The device isolation film 130 is formed by performing a STI process or a LOCOS process in a silicon substrate into which an n-type impurity is implanted. The semiconductor substrate 100 includes a groove 150. The groove 150 is formed in the p well 120. The gate electrode 200 is formed in the groove 150. As the gate electrode 200, materials such as polycrystalline silicon or a metal such as aluminum, copper, tungsten or the like may be used. An upper portion of the gate electrode 200 may project above the uppermost surface of the semiconductor substrate 100. Also, the width of the upper portion of the gate electrode 200 is greater than the width of the bottom portion of the gate electrode 200. In other words, the gate electrode 200 may have a T-shaped cross-section. The gate dielectric film 300 is formed on and/or over the sidewalls and bottom surface of the groove 150 contacting the sidewalls and bottom surface of the gate electrode 200. The gate dielectric film 300 surrounds the sidewalls of the bottom portion of the gate electrode 200 that does not protrude from the uppermost surface of the substrate 100. In other words, the upper portion of the gate electrode 200 is not surrounded by the gate dielectric film 300. The gate dielectric film 300 insulates the sidewalls and bottom surface of the lower portion of the gate electrode 200. As the gate dielectric film 300, materials such as silicon oxide or the like may be used.

The spacer 400 is formed in the groove 150 and adjacent the sidewalls of the gate electrode 200. The spacer 400 is formed on sidewalls of the gate dielectric film 300 and interposed between the gate electrode 200 and the source/drain region 600 to prevent the gate electrode 20 and the source/drain region 600 from short-circuiting. As the spacer 400, material such as nitride or oxide or the like may be used. The LDD region 500 is formed in the p-well 120 below the spacer 400 and the source/drain region 600. The LDD region 500 is formed by implanting low-concentration impurities in the p-well 120. The source/drain region 600 is disposed adjacent sides of the gate electrode 200. More specifically, the source/drain region 600 is disposed on the sidewalls of the spacer 400 by implanting the p-well 120 with high-concentration n-type impurities. The source/drain region 600 is adjacent to the LDD region 500. Also, the source/drain region 600 may include a silicide film including silicide. As shown in example FIG. 3, the spacer 400 and the source/drain region 600 may be formed in the p-well 120 at the same depth.

In accordance with embodiments, the semiconductor device includes the gate electrode 200 formed in the groove 150 of the semiconductor substrate 100, making it possible to prevent the generation of voids between semiconductor devices compared to a semiconductor device structure that forms the gate electrode and spacer on and/or over the uppermost surface of the semiconductor substrate.

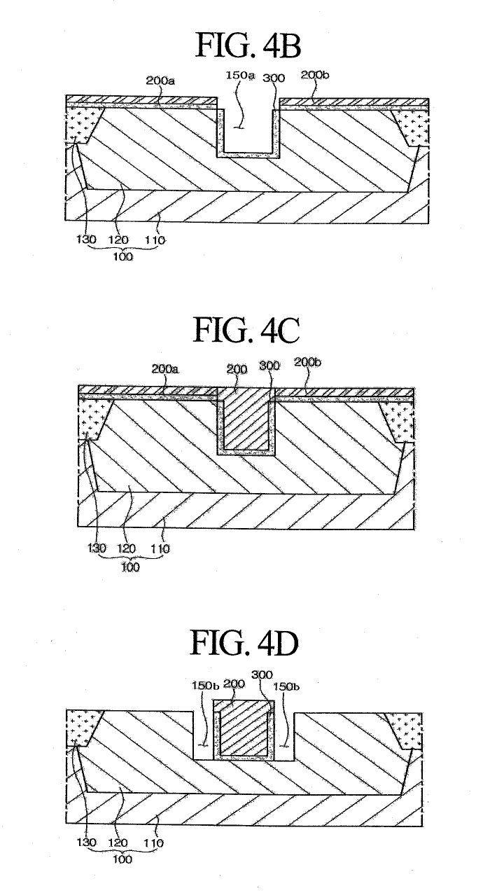

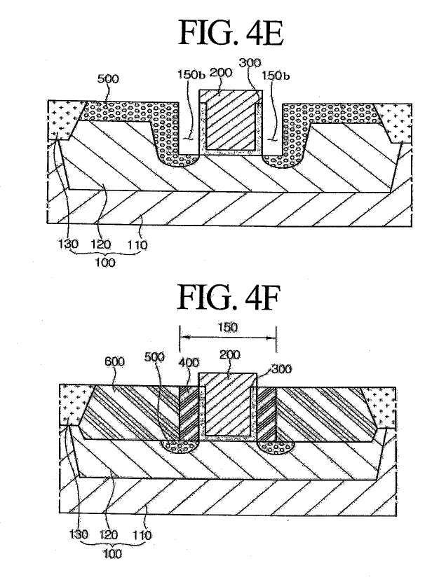

Example FIGS. 4A to 4F are cross-sectional views of a method of fabricating a semiconductor device in accordance with embodiments. Referring to example FIG. 4A, a trench is formed in a silicon substrate to which an n-type impurity is implanted and the trench is filled with oxide, thereby forming a device isolation film 130. Thereafter, a low-concentration p-type impurity is implanted into the silicon substrate to form a p-well 120. Therefore, a semiconductor substrate 100 is formed including the region 110 to which the n-type impurity is implanted, the device isolation film 130 and the p-well 120. Thereafter, an oxide film 200a is formed by performing a thermal oxidation process or a Chemical Vapor Deposition (CVD) process on the semiconductor substrate 100, and a nitride film 200b is formed by performing the CVD process on and/or over the oxide film.

Referring to example FIG. 4B, a first groove 150a is formed by etching the nitride film 200b, oxide film 200a and p-well 120 of the semiconductor substrate 100. Thereafter, a thermal oxidation process is performed on the inner side of the first groove 150a to form a gate dielectric film 300 on and/or over walls of the first groove 150a. As the gate dielectric film 300, material such as silicon oxide may be used.

Referring to example FIG. 4C, material for forming the gate electrode 200 is filled in the first groove 150a and on and/or over the uppermost surface of the nitride film 200b. As the material for forming the gate electrode 200, material such as polycrystalline silicon, copper, aluminum, tungsten or the like may be used. Thereafter, the material for forming the gate electrode 200 is grinded using a CMP process until the nitride film 200b is exposed and the gate electrode 200 is buried in the first groove 150a. The CMP process stops based upon the nitride film 200b as an etch stop layer.

Referring to example FIG. 4D, after the gate electrode 200 is formed, portions of the semiconductor substrate 100 surrounding the gate electrode 200 is etched to form second grooves 150b. More specifically, the p-well 120 of the semiconductor substrate 100 is etched to expose sidewalls of the gate dielectric film 300. In other words, a portion of the inner side surface of the second groove 150b corresponds to the side surface of the gate dielectric film 300. The second groove 150b is formed having a depth corresponding to a depth of the first groove 150a. For example, a depth of the second groove 150b is substantially the same as a depth of the first groove 150a.

Referring to example FIG. 4E, after the second groove 150b is formed, a low-concentration n-type impurity is implanted into the semiconductor substrate 100 to form the LDD region 500. The low-concentration n-type impurity is also implanted under the bottom surface of the second groove 150b.

Referring to example FIG. 4F, a nitride film is formed on and/or over the uppermost surface of the LDD region filling the second groove 150b. The portion of the nitride film formed on and/or over the semiconductor substrate 100 is removed by performing an isotropic etching, such that the nitride film remains in the second groove 150b to thereby form a spacer 400. Thereafter, a high-concentration n-type impurity is implanted into the semiconductor substrate to form a source/drain region 600. The source/drain region 600 is formed on the sidewalls of the spacer 400 and adjacent to the LDD region 500. Thereafter, a metal layer is formed on and/or over the semiconductor substrate 100 and then an annealing process and a cleansing process is performed to thereby form silicide films.

In accordance with embodiments, grooves are formed in the substrate and filled with material for forming gate electrodes, and the material on and/or over the uppermost surface of the semiconductor substrate is removed by performing a CMP process. As the gate electrodes 210 and 200, material such as copper, tungsten or the like may be used. In other words, the material used as the gate electrodes may be material that is difficult to form a pattern through a mask process. Also, the material such as copper and tungsten has lower resistance than aluminum or polycrystalline silicon. Therefore, embodiments can include the gate electrodes having low resistance.

In accordance with embodiments, the semiconductor device and the method of fabricating the same, a gate electrode is formed in a groove formed in the substrate, making it possible to prevent or otherwise reduce void generation. Moreover, the uppermost surface of the semiconductor device is flat since the uppermost surface of the source/drain region and the uppermost surface of the gate electrode can be formed on the same plane, making it possible to easily form the contact electrode, such as the via that is connected electrically to the source/drain region or the gate electrode.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a groove formed in a semiconductor substrate;
a gate dielectric film formed over and contacting a bottom surface of the groove;
a gate electrode formed in the groove over the gate dielectric film;
source/drain regions disposed adjacent the sides of the gate electrode; and
spacers interposed between the gate electrode and the source/drain regions,
wherein the uppermost surface of the source/drain regions, the uppermost surface of the gate electrode and the uppermost surface of the spacers are formed on the same plane.

2. The device of claim 1, further comprising LDD regions formed under and contacting the source/drain regions and contacting the sidewall of the spacers and a bottom surface of the spacers.

3. The device of claim 1, wherein the gate electrode is composed of a poly silicon layer.

4. The device of claim 1, wherein the gate electrode is composed of a metal layer.

5. The device of claim 1, wherein a depth of the spacer is the same as a depth of the source/drain region.

6. A device comprising:
a first groove formed in a semiconductor substrate;
a gate dielectric film formed over and contacting a the sidewalls and the bottom surface of the first groove;
a gate electrode formed in the first groove over the gate dielectric film, the gate electrode including an upper gate electrode portion projecting from the first groove and a lower gate electrode portion formed in the first groove;
second grooves formed in the semiconductor substrate;
spacers formed in a respective one of the second grooves and contacting sidewalls of the gate dielectric film;
source/drain regions formed in the semiconductor substrate and contacting a sidewall of the spacers.

7. The device of claim 6, wherein the second grooves are formed at the same depth as the first groove.

8. The device of claim 6, wherein the width of the upper gate electrode portion is greater than the width of the lower gate electrode portion.

9. The device of claim 6, wherein a depth of the spacer is the same as a depth of the source/drain regions.

10. The device of claim 6, wherein the gate electrode is composed of a poly silicon layer.

11. The device of claim 6, wherein the gate electrode is composed of a metal layer.

12. The device of claim 6, further comprising LDD regions formed under and contacting the bottom surface of source/drain regions and the spacers, respectively.

13. The device of claim 12, wherein the depth of the LDD regions is greater than the depth of the source/drain regions and the spacers.

14. A method comprising:
forming a groove in a semiconductor device; and then
forming spacers in the groove; and then
forming a gate dielectric film over a bottom surface of the groove; and then
forming a gate electrode in the groove between the spacers and over the gate dielectric film; and then
forming LDD regions in the semiconductor device contacting sidewalls and a bottom surface of the spacer; and then
forming source/drain regions in the semiconductor device contacting sidewalls of the spacers and over the LDD regions.

15. The method of claim 14, wherein forming of the LDD regions comprises:
implanting impurities in a region of the semiconductor substrate; and then
performing an annealing process on the region of the semiconductor substrate where the impurities are implanted.

16. The method of claim 14, wherein forming the gate electrode comprises:
forming a gate electrode material over the semiconductor substrate and in the groove; and then
removing a portion of the gate electrode material formed over the semiconductor substrate.

17. The method of claim 14, wherein the gate electrode is composed of a poly silicon layer.

18. The method of claim 14, wherein the gate electrode is composed of a metal layer.

19. The method of claim 14, wherein a depth of the spacers is the same as a depth of the source/drain regions.

20. The method of claim 14, wherein the uppermost surface of the source/drain regions, the uppermost surface of the gate electrode and the uppermost surface of the spacers are formed on the same plane.
